(19) United States
(12) Patent Application Publication
(10) Pub. No.: US 2005/0024078 A1
(43) Pub. Date: Feb. 3, 2005

(54) Device for making pass/fail judgement of semiconductor integrated circuit

(76) Inventor: Tatsuo Takebayashi, Tokyo (JP)

Correspondence Address: MCDERMOTT WILL & EMERY LLP, 600 13th Street, N.W., Washington, DC, 20005-3096, US

(21) Appl. No.: 10/873,622

(22) Filed: Jun. 23, 2004

Related U.S. Application Data
(63) Continuation-in-part of application No. 10/139,652, filed on May 7, 2002.

(30) Foreign Application Priority Data
Nov. 2, 2001 (JP) JP 2001-338156

(51) Int. Cl. G01R 31/26

(52) U.S. Cl. 324/765

(57) ABSTRACT

A pass/fail judgement device for semiconductor integrated circuit has a measuring unit making the pass/fail judgement on measurement items by critical values set in advance on measured data obtained from the chip and outputting the judgement result and the measured data, a pass/fail judgement unit including a measured data memory for storing measured data of chips output from the measuring unit; calculation block for making pass/fail judgement for the content of measured data memory in terms of initial critical value set in advance; a judgement result memory for storing the judgement result; an upper/lower limit value setting block for setting an allowable range of the measured data; and comparing block for judging by comparison whether or not the measured data exceed the upper or lower limit value of the allowable range, and a warning unit for producing a warning based on an output of the comparing block.

### RELATED APPLICATION

This application is a continuation-in-part of application Ser. No. 10/139,652, filed May 7, 2002, titled Device for Making Pass/Fail Judgement of Semiconductor Integrated Circuit, the entire disclosure of which is incorporated herein by reference.

### FIELD OF THE INVENTION

The present invention relates to a device for making a pass/fail judgement on a semiconductor integrated circuit and, in particular, a device which can make a comprehensive judgement for judgement results obtained by an arbitrary number of measurements on specific measurement items and which can change evaluation conditions on the basis of results of the comprehensive evaluation.

### DESCRIPTION OF THE RELATED ART

Conventionally, a semiconductor integrated circuit is manufactured through steps of a wafer process, a wafer test (intermediate test), an assembling (molding) process, and a final test. FIG. 5 is a schematic diagram to show the wafer test (intermediate test) in the prior art technology. In FIG. 5, a reference numeral 101 denotes a wafer and, as shown in FIG. 6, the wafer 101 includes a cluster of chips 102 constituting a semiconductor integrated circuit. A reference numeral 103 denotes a wafer-bearing base movable in the two axial directions of x-axis and y-axis, a reference numeral 104 denotes a measuring unit for measuring the electric characteristics and operating characteristics of each chip 102. A reference numeral 105 denotes a measuring jig mounted on the measuring unit 104 and, as shown in FIG. 7, many probes 106 directly touching the chip 102 at a measuring position are mounted in a projecting manner on the peripheral portion of the measuring jig 105. A reference numeral 107 denotes a transfer unit for moving the wafer-bearing base 103 to transfer the chip 102 to a position opposite to the measuring jig 105. A reference numeral 108 denotes a marking unit for receiving a judgement result combined with a coordinate signal of the chip 102 from the measuring unit 104 and for marking a failing chip with a failing mark.

The measuring unit 104 has a calculation block 111, such as a CPU or the like, which supplies measuring electric power (measuring voltage or measuring current) to the measuring jig 105, and gets measured data from the measuring jig 105 and makes a pass/fail judgement on each chip 102, and a calculation program memory 112 for storing a calculation program and the like including critical values for the pass/fail judgement by the CPU 111.

Next, operation of the device will be described.

The transfer unit 107 of a semiconductor integrated circuit transfers one chip 102 included in the wafer 101 to a measuring position opposite to the measuring jig 105 and puts a terminal fixing portion of the chip 102 into contact with the probes 106 of measuring jig 105. In this state, the measuring unit 104 supplies the probes 106 with measuring electric power (measuring voltage or measuring current), measures characteristics of the chip 102 and makes the pass/fail judgement on the chip 102 for predetermined measurement items in terms of critical values set previously based on the measured data obtained from the probes 106. Then, when the chip 102 is a failing chip, the measuring unit 104 outputs a failing signal to the marking unit 108 and the marking unit 108 which receives the failing signal and the coordinate signal of the chip 102 output from the transfer unit 107, marks the failing chip with a failing mark. In this manner, when the chips 102 are cut away from the wafer 101, thereby being single chips, this failing mark makes it easy to separate the failing chip from others.

A device for making the pass/fail judgement on a semiconductor integrated circuit in the prior art technology is constituted in the manner described above. Thus, the pass/fail judgement on a semiconductor integrated circuit is applied to each chip, and the critical values for the pass/fail judgement are set in an calculation program stored in a memory. Further, there is the case where it is desired that, for example, the critical value is reset again on a measurement item in consideration of variations in one wafer and that the pass/fail judgement is made by the set measurement item, but such pass/fail judgement cannot be made by the device in the prior art technology.

Further, in the case of measurement items having large variations, if the critical values are loose, quality becomes poor and if the critical values are set to be rigorous, yield is reduced. Thus, usually, manufacturers of semiconductor integrated circuits set the critical values at values more rigorous than the specifications required by users and therefore if the pass/fail judgement on the chip is applied to all measurement items in terms of these rigorous critical values, there is produced a problem that the yield might be unnecessarily reduced and cannot be improved.

### SUMMARY OF THE INVENTION

The present invention has been made to solve the above mentioned problems in the prior art technology. It is an object of the present invention to provide a device for making a pass/fail judgement, in which the pass/fail judgement on a semiconductor integrated circuit can be applied to specific measurement items in terms of the critical values different from ordinary ones, in other words, in which the critical values are determined in comprehensive consideration of the judgement results of respective chips of the semiconductor integrated circuit by an arbitrary unit, for example, by one wafer or by one lot (collection of a predetermined number of wafers) thereby to prevent an unnecessary decrease in the yield.

A device for making the pass/fail judgement in accordance with one aspect of the present invention includes a transfer unit for transferring one chip among many chips included in a wafer to a measuring position and outputting a coordinate signal of the chip positioned at the measuring position; a measuring unit for supplying the chip transferred to the measuring position with measuring electric power and for making the pass/fail judgement for the chip on measurement items in terms of critical values set previously based on measured data obtained from the chip and for outputting the judgement result and the measured data; a pass/fail judgement unit for receiving the measured data and the coordinate signal of the chip and for making the pass/fail judgement for the chip on a measurement item other than the measurement items in terms of critical values different from the critical values; and the pass/fail judgement unit comprises a measured data memory for storing the measured data of respective chips output from the measuring unit; a calculation block for making the pass/fail judgement for the content of the measured data memory in terms of an initial critical value set in advance; a judgement result memory for storing the judgement result; an upper/lower limit value setting block for setting an allowable range of the measured data; and a comparing block for judging by comparison whether or not the measured data exceeds the upper or lower limit value of the allowable range, and the device further comprising a warning unit for producing a warning based on output of the comparing block.

In the device for making the pass/fail judgement for a semiconductor integrated circuit according to another aspect of the present invention the initial critical value is changed in the range of a specification required by user.

In the device for making the pass/fail judgement for a semiconductor integrated circuit according to yet another aspect of the present invention, a chip necessary for being marked is marked based on the judgement result.

### BRIEF DESCRIPTION OF THE DRAWINGS

FIG. 1 is a block diagram showing an outline of a device for making a pass/fail judgement for a semiconductor integrated circuit in accordance with an embodiment of the present invention.

FIG. 2 is a block diagram showing the configuration of a pass/fail judgement unit of the device.

FIG. 3 is a flowchart explaining the operation of the device for making a pass/fail judgement.

FIG. 4 is a diagram showing an effect of changing a critical value.

FIG. 5 is a block diagram showing an outline of a device for making a pass/fail judgement for a semiconductor integrated circuit in the prior art technology.

FIG. 6 is a plan view showing a semiconductor wafer.

FIG. 7 is a plan view of chip separated from a wafer.

### DESCRIPTION OF THE PREFERRED EMBODIMENTS

The preferred embodiments in accordance with the present invention will be described below.

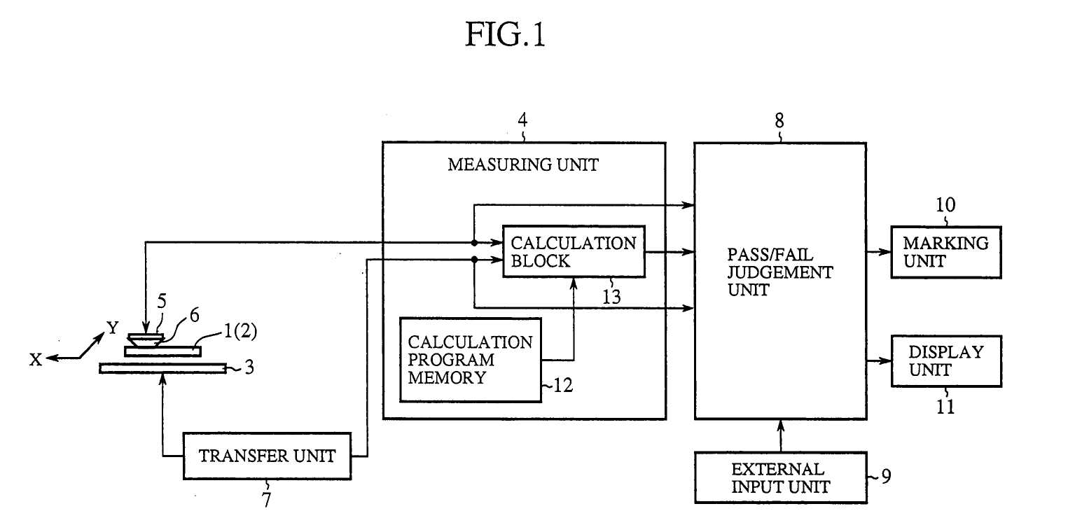

FIG. 1 is a schematic diagram showing a device for making a pass/fail judgement for a semiconductor integrated circuit in accordance with the present invention which conducts a wafer test (intermediate test). In FIG. 1, a reference numeral 1 denotes a wafer including a cluster of chips 2 constituting a semiconductor integrated circuit. A reference numeral 3 denotes a wafer-bearing base movable in the two axial directions of x-axis and y-axis, a reference numeral 4 denotes a measuring unit of a semiconductor integrated circuit for measuring the electric characteristics and operating characteristics of each chip 2. A reference numeral 5 denotes a measuring jig mounted on the measuring unit 4 and, as shown in FIG. 7, many probes 6 directly touching the chip 2 at a measuring position are mounted in a projecting manner on the peripheral portion of measuring jig 5. A reference numeral 7 denotes a transfer unit of a semiconductor integrated circuit for moving the wafer-bearing base 3 to transfer the chip 2 to a position opposite to the measuring jig 5. A reference numeral 8 denotes a pass/fail judgement unit for making a pass/fail judgement for each chip 2 on specified measurement items for which measurement is not made by the measuring unit 4, a reference numeral 9 denotes an external input unit for changing and inputting critical values to the pass/fail judgement unit 8, a reference numeral 10 denotes a marking unit for marking a failing chip with a failing mark based on the judgement results from the pass/fail judgement unit 8 and the chip coordinate signals corresponding to the judgement results from the transfer unit 7, and a reference numeral 11 denotes a display unit for displaying the judgement results from the pass/fail judgement unit 8.

At this point, because operations of the marking unit 10 and the display unit 11 are quite the same as those in the prior art technology, explanation for those units will be omitted in the following description.

The measuring unit 4 has a calculation block 13, such as a CPU or the like, which supplies the measuring jig 5 with measuring electric power (measuring voltage or measuring current) and receives measured data from the measuring jig 5 and makes the pass/fail judgement for each chip 2 on the basis of measured data, and an calculation program memory 12 for storing a calculation program and the like used for the pass/fail judgement for the calculation block 13.

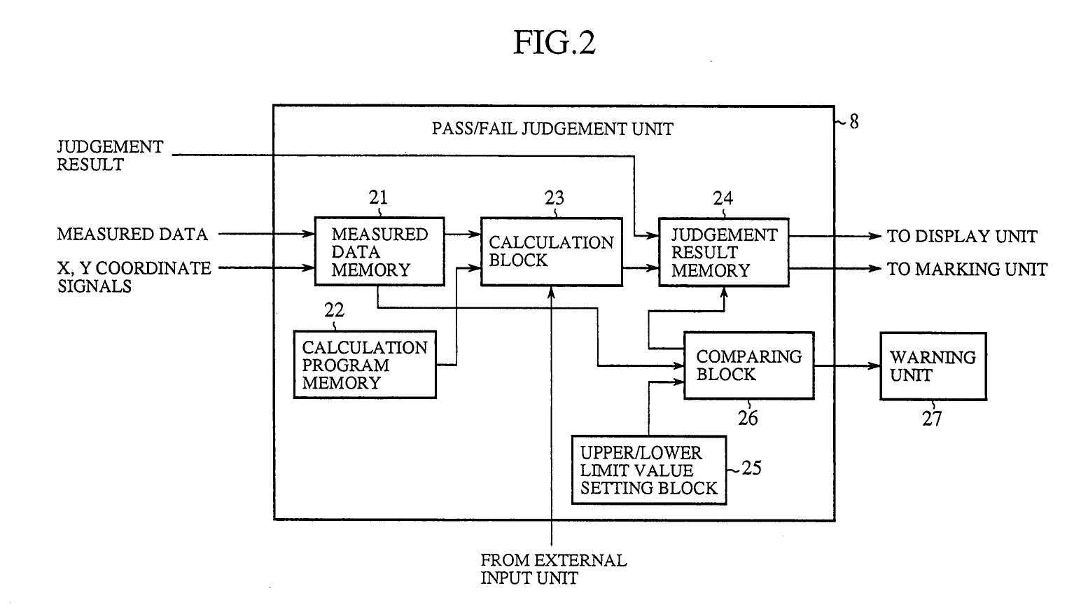

The pass/fail judgement unit 8, as shown in FIG. 2, has a measured data memory 21 which is supplied with the measured data from the measuring unit 4 and the X, Y coordinate signals of a chip at the measuring position from the transfer unit 7 and stores the measured data and the X, Y coordinate signals in association with each other, a calculation program memory 22 for storing the initial critical values for the pass/fail judgement and a calculation program for the pass/fail judgement, a calculation block 23 for making the pass/fail judgement for each chip for the specific measurement items based on the output signals from the memories 21 and 22, a judgement result memory 24 for storing the judgement results and displaying the stored contents on the display unit 11 at a time, for example, after making the pass/fail judgement for all the chips included in one wafer is finished, an upper/lower limit value setting block 25 for setting upper and lower limit values (allowable range) for the measured data in the measured data memory 21, a comparing block 26 for judging by comparison whether or not the measured data from the measured data memory 21 exceeds the upper or lower limit value in a predetermined number of measurement, and a warning unit 27 for producing a warning based on an output of the comparing block 26.

Next, operation of the pass/fail judgement unit 8 will be described.

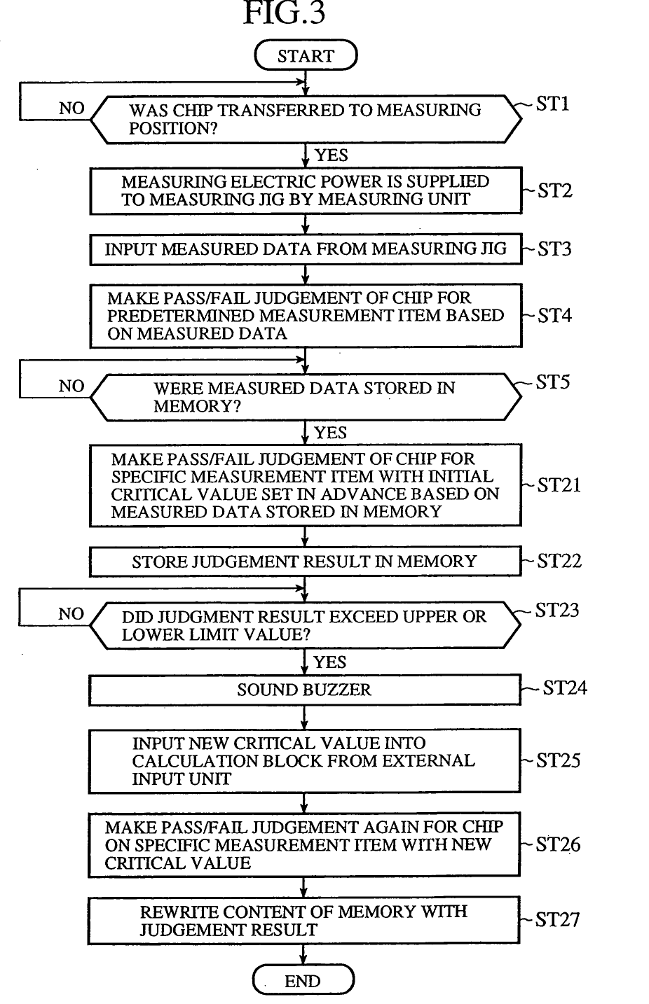

FIG. 3 is a flowchart to explain the operation of the pass/fail judgement unit 8. First, it is confirmed whether or not one of the chips 2 included in a wafer 1 is transferred to a measuring position by the transfer unit 7 (step ST1). If the confirmed result is YES, the measuring unit 4 supplies the measuring jig 5 with measuring electric power (measuring voltage or measuring current) (step ST2). Then, measured data from the measuring jig 5 is input to the measuring unit 4 (step ST3) and the calculation block 13 makes the pass/fail judgement for the chip 2 for the desired measurement items in terms of the critical values set in the calculation program memory 12 (step ST4).

For example, in the case where there are the following measurement items:

Operating Characteristics

A: (5 V, 20 kHz)
B: (3 V, 20 kHz)
C: (2 V, 10 kHz)
   Electric Characteristics
A: (amount of current: 10 mA or less)
B: (maximum rated voltage: up to 6 V)
C: (leakage current when operation stops)
   when it is desired that for the measurement item C of electric characteristics, the critical value is set in consideration of variations in one wafer, for example, and then the pass/fail judgement is made, the foregoing measuring unit 4 makes the pass/fail judgement for the chip 2 only for the operating characteristics A, B, and C and the electric characteristics A and B, and then the pass/fail judgement unit 8 disposed at the latter stage makes the pass/fail judgement for the chip 2 for the electric characteristic C.

Then, the measuring unit 4 makes the pass/fail judgement on the Operating characteristics A, B and C, and Electric characteristics A and B for all the chips 2 included in one wafer 1 and confirms whether or not the measured data are stored in the measured'data memory 21 (step ST5) and if the result is NO, the measuring unit 4 continues the measuring operation until it finishes making the pass/fail judgement on the above described five measurement items for all the chips 2.

If the confirmed result of step ST5 is YES, the pass/fail judgement for chip 2 on the measurement item of electric characteristic C (specific measurement item) in terms of the initial critical value set previously, is made by the calculating block 23 based on the measured data stored in the measured data memory 21 (step ST21). The judgement result is stored in sequence in the judgement result memory 24 (step ST22), and when the pass/fail judgement of, for example, all the chips 2 included in the one wafer 1 is finished, the comparing block 26 confirms whether or not the measured data for a specific measurement item accumulated in the measured data memory 21 exceeds in a predetermined frequency the upper or lower limit value read from the upper/lower limit value setting block 25 (step ST23).

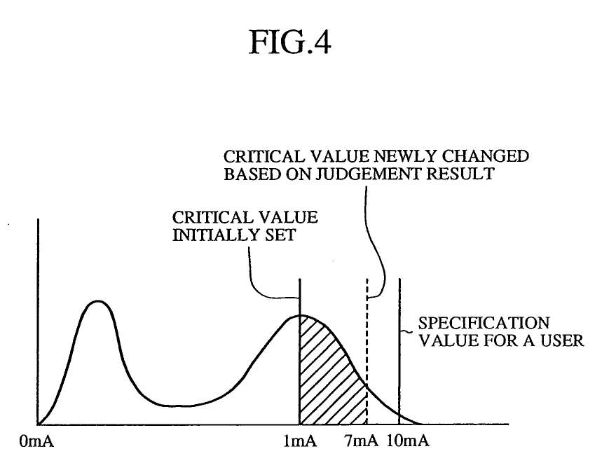

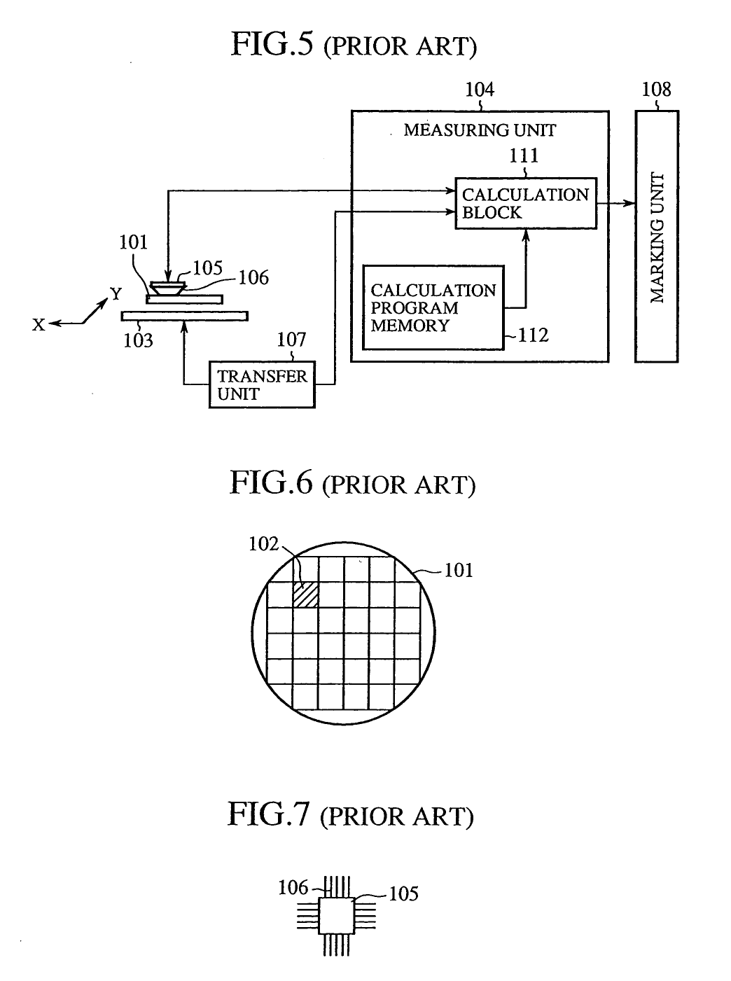

If the confirmed result is YES, the process sounds buzzer of the warning unit 27 (step ST24) and waits till a new critical value is input to the calculation block 23 by the use of the external input unit 9 (step ST25). For example, as shown in FIG. 4, in the case where the initial critical value is 1 mA and the specification value for the user is 10 mA, a new critical value is set at 7 mA and the pass/fail judgement for the measured data accumulated in the measured data memory 21 is made again for the measurement item of electric characteristic C (step ST26), and the contents of the judgement result memory 24 are rewritten with the judgement results (step ST27). To display the judgement results rewritten, the comparing block 26 informs the judgement result memory 24 that a new critical value is input to the calculation block 23 (i.e., the measured data exceeds the upper or lower limit value). This is the end of pass/fail judgement operation.

According to the embodiment, in the case where the measured data exceeds in a predetermined frequency the upper or lower limit value set in advance for the measurement item of a specific item, a warning is given automatically and thus it is possible to change the initial critical value to the new critical value without fail and to surely prevent an unnecessary decrease in the yield.

As above described, according to the present invention, there is produced an effect to comprehensively evaluate the judgement results in terms of an arbitrary number of measurements, for example, one wafer, a plurality of wafers or one lot for making the pass/fail judgement according to the circumstances and an effect to change the critical value to a new critical value without fail for surely preventing an unnecessary decrease in the yield.

According to the present invention, there is produced an effect to make product quality supplied to the user always satisfy the specification required by the user with preventing the yield of a product from being decreased more than required.

According to the present invention, there is produced an effect to always suitably mark the chip.

This application claims priority to Japanese Patent Application Number 2001-338156, filed on Nov. 2, 2001, the entire disclosure of which is incorporated herein by reference.

1. A device for making a pass/fail judgement for semiconductor integrated circuit comprising:
a transfer unit for transferring one chip among many chips included in a wafer to a measuring position and outputting a coordinate signal of the chip positioned at the measuring position;
a measuring unit for supplying said chip transferred to said measuring position with measuring electric power and for making the pass/fail judgement for said chip on measurement items in terms of critical values set previously based on measured data obtained from said chip and for outputting the judgement result and said measured data;
a pass/fail judgement unit for receiving said measured data and said coordinate signal of the chip and for making the pass/fail judgement for said chip on a measurement item other than said measurement items in terms of critical values different from said critical values; wherein
said pass/fail judgement unit comprises
a measured data memory for storing the measured data of respective chips output from the measuring unit;
a calculation block for making the pass/fail judgement for the content of the measured data memory in terms of an initial critical value set in advance;
a judgement result memory for storing the judgement result;
an upper/lower limit value setting block for setting an allowable range of the measured data; and
a comparing block for judging by comparison whether or not the measured data exceeds the upper or lower limit value of the allowable range,
said device further comprising a warning unit for producing a warning based on output of said comparing block.

2. The device for making the pass/fail judgement for a semiconductor integrated circuit according to claim 1, wherein the initial critical value is changed in the range of a specification required by user.

3. The device for making the pass/fail judgement for a semiconductor integrated circuit according to claim 1, wherein a chip necessary for being marked is marked based on the judgement result.
